(19) United States
(12) Patent Application Publication
(10) Pub. No.: US 2009/0200494 A1
(43) Pub. Date: Aug. 13, 2009

(54) TECHNIQUES FOR COLD IMPLANTATION OF CARBON-CONTAINING SPECIES

(75) Inventors: Christopher R. Hatem, Cambridge, MA (US); Anthony Renau, West Newbury, MA (US); Gary E. Dickerson, Gloucester, MA (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: VARIAN SEMICONDUCTOR EQUIPMENT ASSOCIATES, INC., GLOUCESTER, MA (US)

(21) Appl. No.: 12/059,437

(22) Filed: Mar. 31, 2008

Related U.S. Application Data
(60) Provisional application No. 61/027,563, filed on Feb. 11, 2008.

(51) Int. Cl. H01J 37/08

(52) U.S. Cl. 250/492.21

(57) ABSTRACT

Techniques for cold implantation of carbon-containing species are disclosed. In one particular exemplary embodiment, the techniques may be realized as an apparatus for ion implantation including a cooling device for cooling a target material to a predetermined temperature, and an ion implanter for implanting the target material with a carbon-containing species at the predetermined temperature to improve at least one of strain and amorphization.

### CROSS-REFERENCE TO RELATED APPLICATIONS

This patent application claims priority to U.S. Provisional Patent Application No. 61/027,563, filed Feb. 11, 2008, which is hereby incorporated by reference herein in its entirety.

### FIELD OF THE DISCLOSURE

The present disclosure relates generally to ion implantation and, more particularly, to techniques for cold implantation of carbon-containing species.

### BACKGROUND OF THE DISCLOSURE

Ion implantation is a process of depositing chemical species into a substrate by direct bombardment of the substrate with energized ions. In semiconductor manufacturing, ion implanters are used primarily for doping processes that alter the type and level of conductivity of target materials. A precise doping profile in an integrated circuit (IC) substrate and its thin-film structure is often crucial for proper IC performance. To achieve a desired doping profile, one or more ion species may be implanted in different doses and at different energy levels.

Moreover, ion implantation is currently the most common technique for introducing conductivity-altering impurities into semiconductor wafers. A desired impurity material is ionized in an ion source, generated ions are accelerated to form an ion beam of prescribed energy, and the ion beam is directed at the surface of a semiconductor wafer. Energetic ions in the ion beam penetrate into the bulk of semiconductor material in the semiconductor wafer and are embedded into the crystalline lattice of the semiconductor material to form a region of desired conductivity.

An ion implanter typically includes an ion source for converting a gas or a solid material into a well-defined ion beam. The ion beam is usually mass analyzed to eliminate undesired ion species, accelerated to a desired energy, and directed to a target. The ion beam may be distributed over the target area by beam scanning, by target movement, or by a combination of beam scanning and target movement. The ion beam may be a spot beam or a ribbon beam having long and short dimensions.

Carbon may be used as a co-implant species in association with another pre-amorphization implant (PAI) species, such as germanium, boron, etc. The idea is to position the carbon between a shallow dopant and end-of-range (EOR) damage caused by the PAI species. Substitutional carbon may block some interstitials coming back from EOR during an anneal that would otherwise cause transient enhanced diffusion (TED) and boron interstitial cluster (BIC) formation. However, the range of carbon often overlaps with that of the PAI species, and so the carbon implant itself contributes to PAI. Thus, carbon itself may also be used as a pre-amorphization species.

Carbon may also be used to create localized compressive strain. Therefore, if a source/drain in a transistor device created from SiC, carbon implantation may cause tensile strain in a channel of the transistor device. This may improve n-type metal-oxide-semiconductor (NMOS) behavior. Incorporating carbon into a silicon lattice of the transistor material may require the use of epitaxial growth or the implantation a high dose of carbon into the silicon lattice may cause amorphization, and the carbon, in regrowth, may be incorporated into the silicon lattice. As a result, amorphization and stress are both important factors considered by semiconductor manufacturers.

Accordingly, in view of the foregoing, it may be understood that there are significant problems and shortcomings associated with current technologies for ion implantation, and more particularly, for implanting carbon-containing species.

### SUMMARY OF THE DISCLOSURE

Techniques for cold implantation of carbon-containing species are disclosed. In one particular exemplary embodiment, the techniques may be realized as a method for ion implantation that may include cooling a target material to a predetermined temperature, and implanting the target material with a carbon-containing species at the predetermined temperature to improve at least one of strain and amorphization.

In accordance with other aspects of this particular exemplary embodiment, the target material may be cooled by at least one of a backside cooling, thermal conditioning cooling, and pre-chilling.

In accordance with further aspects of this particular exemplary embodiment, the predetermined temperature may be below room temperature and above −212° C. For example, the predetermined temperature may be in the range of −20° C. to −100° C.

In accordance with additional aspects of this particular exemplary embodiment, the carbon-containing species may be molecular carbon comprising at least one of carbon, diborane, pentaborane, carborane, octaborane, decaborane, and octadecaborane.

In accordance with other aspects of this particular exemplary embodiment, the carbon-containing species may be an alkane or alkene comprising at least one of methane, ethane, propane, bibenzyl, butane, and pyrene.

In accordance with further aspects of this particular exemplary embodiment, the method may further include implanting the target material with an additional species for improved pre-amorphization implantation (PAI) or improved conductance of the target material. For example, the additional species may include at least one of germanium (Ge), boron (B), phosphorus (P), silicon (Si), arsenic (As), xenon (Xe), carbon (C), nitrogen (N), aluminum (Al), magnesium (Mg), silver (Ag), gold (A), carborane (C₂B₁₀H₁₂), boron difluoride (BF2), decaborane, octadecaborane, and diborane.

In accordance with additional aspects of this particular exemplary embodiment, the method may be used to at least create strain and fabricate an ultra-shallow junction (USJ) in the target material.

In accordance with additional aspects of this particular exemplary embodiment, the method may further include controlling at least one of dose, dose rate, number of atoms in the carbons containing species, atomic energy, and pressure to further improve at least one of strain and amorphization.

In accordance with another exemplary embodiment, the technique may be realized an apparatus for ion implantation that may include a cooling device for cooling a target material to a predetermined temperature, and an ion implanter for implanting the target material with a carbon-containing species at the predetermined temperature to improve at least one of strain and amorphization.

In accordance with additional aspects of this particular exemplary embodiment, the cooling device may include at least one of a backside cooling device, a thermal conditioning unit, and a pre-chiller.

In accordance with another exemplary embodiment, the technique may be realized an apparatus for ion implantation that may include a means for cooling a target material to a predetermined temperature, and a means for implanting the target material with a carbon-containing species at the predetermined temperature to improve at least one of strain and amorphization.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 depicts a partial cross-sectional view of a plasma doping system according to an embodiment of the present disclosure.

FIG. 2 depicts a beam-line ion implanter according to an embodiment of the present disclosure.

FIG. 3 depicts a chuck for performing backside gas thermal coupling according to an embodiment of the present disclosure.

FIG. 4 depicts an exemplary graph illustrating the effect of ethane compared to carbon monomers according to an alternative embodiment of the present disclosure.

FIG. 5 depicts an exemplary graph illustrating the effect of temperature on carbon implantation according to an alternative embodiment of the present disclosure.

FIG. 6 depicts an exemplary graph illustrating and comparing carbon dose and amorphous thickness for various carbon implants according to an alternative embodiment of the present disclosure.

### DETAILED DESCRIPTION OF EXEMPLARY EMBODIMENTS

Embodiments of the present disclosure provide an apparatus and method for cold implantation of carbon-containing species.

Carbon-containing species may be implanted into a workpiece, such as, for example, a semiconductor wafer. The formulae of these carbon-containing species vary widely. Accordingly, in formulae presented in the present disclosure, B represents boron, C represents carbon, and Si represents silicon. X and Y each represent at least one element. In some cases, X and/or Y may represent single elements (e.g., X=C, Y=H); and, in other cases, X and/or Y may represent more than one element (e.g., X=NH₄, NH₃, CH₃). Also, it should be appreciated, for example, that a formula such as CBY may be represented by other equivalent chemical formulas that may include the same elements in a different order such as BCY or CYB. In some embodiments of the present disclosure, the formulae may be represented by the CₐB_{b}Y_{c}, where a>0, b>0 and c>0.

In some situations, Y may represent at least hydrogen (e.g., the formula comprises CₐB_{b}H_{c}). It should be appreciated that, in some embodiments, derivatives of XₐB_{b}H_{c} may be used which contain other elements or groups of elements (e.g., CH₃) which replace hydrogen at X and/or B sites. It should also be appreciated that substituents may be any suitable inorganic or organic species.

In addition, a formula CₐB_{b}H_{c} may be used in one embodiment. It should be understood that, in another embodiment, derivatives of CₐB_{b}H_{c} may be used which contain other elements or groups of elements which replace hydrogen at C and/or B sites. Again, it should be appreciated that substituents may be any suitable inorganic or organic species. In another embodiment, a formula may comprise carborane, C₂B₁₀H₁₂.

It should be appreciated that the carbon-containing species may not be limited solely to molecules with the formulas CBY or XBY. In fact, these carbon-containing species may be molecular or atomic. For example, the carbon-containing species may be decaborane or octadecaborane. In other examples, the carbon-containing species may be an alkane such as methane, ethane, propane, or butane. Furthermore, the carbon-containing species may also be pyrene or any other species, atomic or molecular, that include at least one carbon atom.

Use of a carbon-containing species may increase amorphization of a workpiece. Furthermore, use of molecular carbon-containing species may increase the amount of carbon that is implanted at a given beam energy due to the number of carbon atoms per molecule.

Accordingly, embodiments of the present disclosure may provide ion implantation systems and method to improve amorphization caused by carbon-containing species. There are numerous parameters that may be adjusted to improve amorphization. First, for example, increasing dose may cause an amorphous/crystalline interface of a workpiece to become deeper, thereby improving amorphization. However, such amorphization may be limited because gate-induced diode leakage (GIDL) may tend to be associated with carbon.

Second, dose rate may also be increased to improve amorphization because such an increase may also cause an amorphous/crystalline interface of a workpiece to become deeper. However, this effect may be limited by the ability of an ion source to produce beam currents.

Third, increasing the number of atoms in a molecule may amorphize a workpiece more rapidly and more deeply as well. As such, this may have a similar effect to changing the dose rate.

Molecules may also share total energy among constituent atoms according to their respective masses. For instance, in deep implants, atoms may have high energy and this high energy may be limited by the ability of magnets in an ion implanter to bend or may be limited by acceleration voltages that are available.

Fourth, amorphization may be improved by decreasing temperature of a workpiece. For example, damage may persist longer after an ion has stopped, allowing further damage from increased collision cascades to overlap. This may be important to carbon because carbon is a light atom that does not produce dense collision cascades. Thus, for heavier species, such as germanium, temperature effects may be smaller. However, decreasing temperature may ultimately produce deeper amorphization and a smoother amorphous/crystalline interface.

Ultimately, this may lead to reduced damage after regrowth, such as solid phase epitaxial regrowth (SPER).

It should be appreciated that ethane, for exemplary purposes, may be used to take advantage of many of the above-described methods to improve amorphization. For example, ethane may be produced in a standard ion source (e.g., an indirectly heated cathode) with simple precursors (e.g., ethane, propane, etc.), and cold temperatures may be used to improve amorphization with ethane. It should be appreciated that other carbon-containing species similar to ethane may also be used.

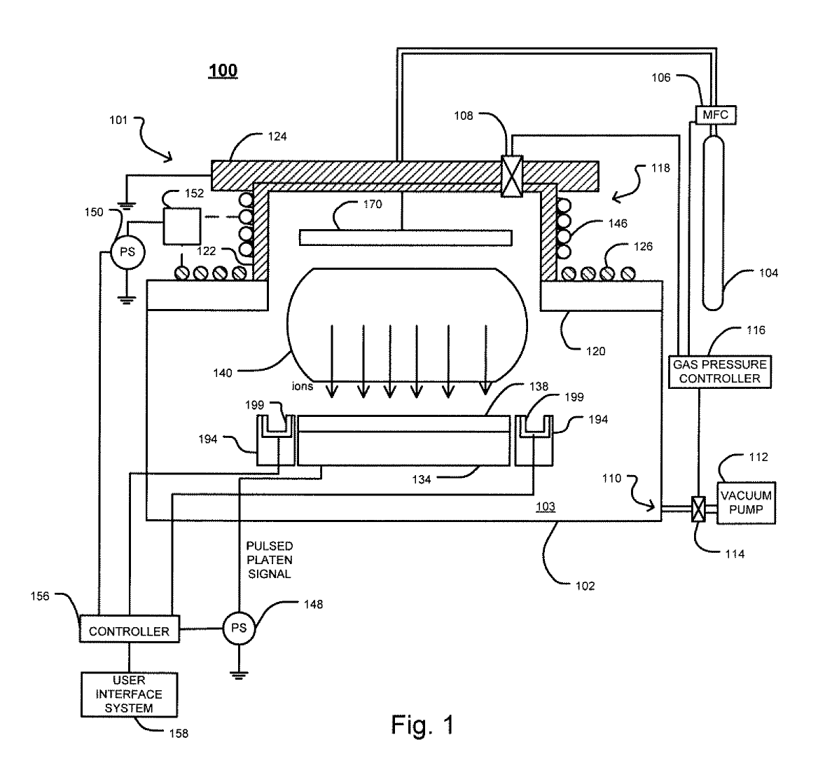

FIG. 1 depicts a plasma doping system 100 according to an embodiment of the present disclosure. Referring to FIG. 1, the plasma doping system 100 may include a process chamber 102 defining an enclosed volume 103. A platen 134 may be positioned in the process chamber 102 to support a workpiece 138. In one embodiment, the workpiece 138 may be a semiconductor wafer having a disk shape. For example, a 300 millimeter (mm) diameter silicon wafer may be used. In another embodiment, the workpiece 138 may be clamped to a flat surface of the platen 134 by electrostatic or mechanical forces. In yet another embodiment, the platen 134 may include conductive pins (not shown) for forming a connection to the workpiece 138. Other various embodiments may also be provided.

The plasma doping system 100 may also include a gas source 104 to provide a dopant gas to the enclosed volume 103 through a mass flow controller 106. A gas baffle 170 is may be positioned in the process chamber 102 to deflect a flow of gas from the gas source 104. A pressure gauge 108 be provided to measure the pressure inside the process chamber 102. A vacuum pump 112 may be utilized to evacuate exhaust from the process chamber 102 through an exhaust port 110 in the process chamber 102. An exhaust valve 114 may control the exhaust conductance through an exhaust port 110.

The plasma doping system 100 may further include a gas pressure controller 116 that is electrically connected to the mass flow controller 106, the pressure gauge 108, and the exhaust valve 114. The gas pressure controller 116 may be configured to maintain a desired pressure in the process chamber 102 by controlling either exhaust conductance with the exhaust valve 114 or a process gas flow rate with the mass flow controller 106 in a feedback loop that is responsive to the pressure gauge 108.

The process chamber 102 may have a chamber top 118 that includes a first section 120 formed of a dielectric material that extends in a generally horizontal direction. The chamber top 118 may also include a second section 122 formed of a dielectric material that extends a height from the first section 120 in a generally vertical direction. The chamber top 118 may further include a lid 124 formed of an electrically and thermally conductive material that extends across the second section 122 in a horizontal direction. The lid 124 may also be grounded.

The plasma doping system 100 may further include a source configuration 101 configured to generate a plasma 140 within the process chamber 102. The source configuration 101 may include an RF source 150, such as a power supply, to supply RF power to either one or both of a planar RE antenna 126 and a helical RF antenna 146 to generate the plasma 140. The RF source 150 may be coupled to the antennas 126, 146 through an impedance matching network 152. In one embodiment, the impedance matching network 152 may match the output impedance of the RF source 150 to the impedance of the RF antennas 126, 146 in order to maximize the power transferred from the RF source 150 to the RF antennas 126, 146. Other various configurations may also be provided.

The plasma doping system 100 may also include a bias power supply 148 electrically coupled to the platen 134. In one embodiment, the bias power supply 148 may be configured to provide a pulsed platen signal having pulse ON and OFF time periods to bias the platen 134, and, hence, the workpiece 138, and to accelerate ions from the plasma 140 toward the workpiece 138 during the pulse ON time periods and not during the pulse OFF periods. The bias power supply 148 may be a DC or an RF power supply. Other variations may also be utilized.

The plasma doping system 100 may further include a shield ring 194 disposed around the platen 134. The shield ring 194 may be biased to improve the uniformity of implanted ion distribution near the edge of the workpiece 138. One or more Faraday sensors, such as an annular Faraday sensor 199, may be positioned in the shield ring 194 to sense ion beam current.

The plasma doping system 100 may further include a controller 156 and a user interface system 158. In one embodiment, the controller 156 may be a general-purpose computer or a network of general-purpose computers that are programmed to perform desired input/output functions. In another embodiment, the controller 156 may include or also include other electronic circuitry or components, such as application-specific integrated circuits, other hardwired or programmable electronic devices, discrete element circuits, etc. In yet another embodiment, the controller 156 may include or also include communication devices, data storage devices, and software. It should be appreciated that while the controller 156 of FIG. 1 is illustrated as providing only output signals to the power supplies 148, 150, and receiving input signals from the Faraday sensor 199, the controller 156 may also provide output signals to and receive input signals from other components of the plasma doping system 100. Other various embodiments may also be provided.

The user interface system 158 may include various devices to allow a user to input commands and/or data and/or to monitor the plasma doping system 100 via the controller 156. These may include touch screens, keyboards, user pointing devices, displays, printers, etc. Other various devices may also be utilized.

In operation, the gas source 104 may supply a primary dopant gas containing a desired dopant for implantation into the workpiece 138. A variety of a primary dopant gases may be used. For example, in one embodiment, the primary dopant gas may be Si, C, N, Ge, Sn, Al, Mg, Ag, Au, or combinations thereof. In another embodiment, the primary dopant gas may also be or may also include, arsenic, boron, phosphorus, carborane C₂B₁₀H₁₂, or other large molecular compounds. In yet another embodiment, the primary dopant gas may be an alkane or another atomic or molecular carbon-containing species. Other various primary dopant gas embodiments may also be provided.

The gas pressure controller 116 may regulate the rate at which the primary dopant gas is supplied to the process chamber 102. The source configuration 101 may operate to generate the plasma 140 within the process chamber 102. The source configuration 101 may be controlled by the controller 156. To generate the plasma 140, the RF source 150 may resonate RF currents in at least one of the RF antennas 126, 146 to produce an electromagnetic field (e.g., an oscillating, a DC, or an RF field) in the process chamber 102, which in turn may excite and ionize the primary dopant gas in the process chamber 102 to generate the plasma 140.

The bias power supply 148 may provide a pulsed platen signal to bias the platen 134 and, hence, the workpiece 138 to accelerate ions from the plasma 140 toward the workpiece 138 during the pulse ON periods of the pulsed platen signal. The frequency of the pulsed platen signal and/or the duty cycle of the pulses may be selected to provide a desired dose rate. The amplitude of the pulsed platen signal may be selected to provide a desired energy. With all other parameters being equal, a greater energy will result in a greater implanted depth.

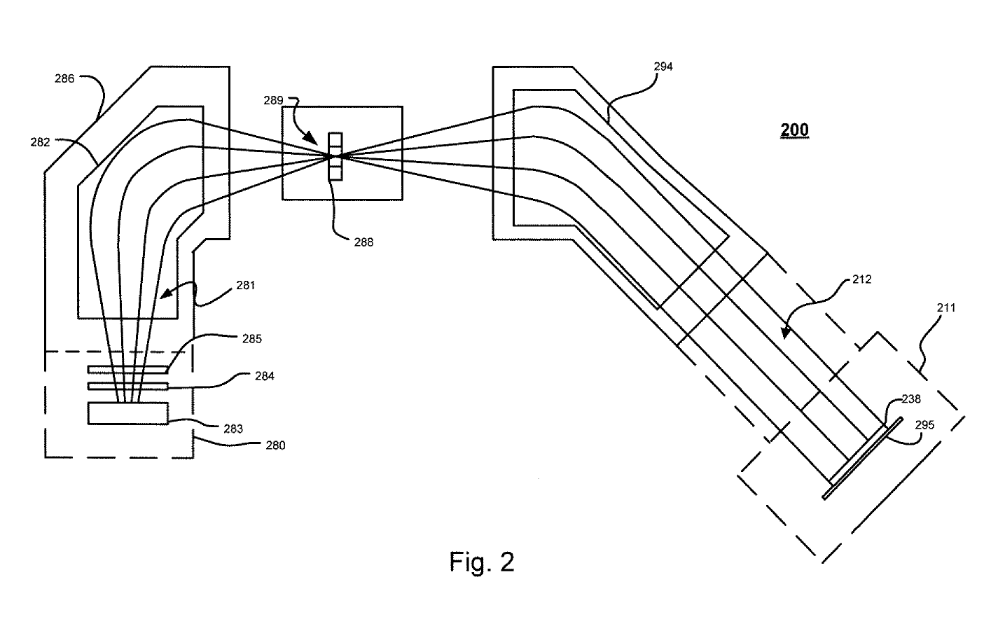

FIG. 2 depicts a beam-line ion implanter 200 according to an embodiment of the present disclosure. Referring to FIG. 2, the beam-line ion implanter 200 may include an ion source 280 to generate ions that form an ion beam 281. The ion source 280 may include an ion chamber 283 and a gas box (not shown) containing a gas to be ionized. The gas may be supplied to the ion chamber 283 where it is ionized. In one embodiment, this gas may be or may include arsenic, boron, phosphorus, carborane C₂B₁₀H₁₂, or other large molecular compound. In another embodiment, the gas may be an alkane or other atomic or molecular carbon-containing species. The ions formed may be extracted from the ion chamber 283 to form the ion beam 281.

The ion beam 281 may be directed between the poles of a resolving magnet 282. A power supply may be connected to an extraction electrode (not shown) of the ion source 280 and may provide an adjustable voltage. For example, a voltage of approximately 0.2 to 80 kV in a high current ion implanter may be provided. Thus, singly charged ions from the ion source 280 may be accelerated to energies of about 0.2 to 80 keV by this adjustable voltage.

The ion beam 281 may pass through a suppression electrode 284 and a ground electrode 285 to a mass analyzer 286. As depicted in FIG. 2, the mass analyzer 286 may include the resolving magnet 282. The mass analyzer 286 may direct the ion beam 281 to a masking electrode 288 having a resolving aperture 289. In another embodiment, a mass analyzer 286 may include the resolving magnet 282 and the masking electrode 288 having the resolving aperture 289. The resolving magnet 282 may deflect ions in the ion beam 281 such that ions of a desired ion species may pass through the resolving aperture 289. Undesired ion species may not pass through the resolving aperture 289. Instead, such undesired ion species may be blocked by the masking electrode 288. In one embodiment, for example, the resolving magnet 282 may deflect ions of the desired species by about 90°.

Ions of the desired ion species may pass through the resolving aperture 289 to an angle corrector magnet 294. The angle corrector magnet 294 may then deflect ions of the desired ion species and convert the ion beam from a diverging ion beam into ribbon ion beam 212, containing ions which may have substantially parallel trajectories. In one embodiment, for example, the angle corrector magnet 294 may deflect ions of the desired ion species by about 70°. In another embodiment, the beam-line ion implanter 200 may also include acceleration or deceleration units. Other various embodiments may also be provided.

An end station 211 may support one or more workpieces, such as workpiece 238, in the path of the ribbon ion beam 212 such that ions of the desired species may be implanted into workpiece 138. The end station 211 may include a platen 295 to support the workpiece 238. The end station 211 also may include a scanner (not shown) for moving the workpiece 238 perpendicular to a long dimension of a cross-section of the ribbon ion beam 212, thereby distributing ions over the entire surface of workpiece 238. It should be appreciated that although the ribbon ion beam 212 is depicted in FIG. 2, other various beams and embodiments may be provided, such as, for example, a spot beam.

The ion implanter 200 may include additional components. For example, in one embodiment, the end station 211 may also include automated workpiece handling equipment for introducing workpieces into the beam-line ion implanter 200 and for removing workpieces after ion implantation. In another embodiment, the end station 211 may also include a dose measuring system, an electron flood gun, or other similar components. It should be appreciated that the entire path traversed by the ion beam 212 may also be evacuated during ion implantation. Furthermore, it should be appreciated that the beam-line ion implanter 200 may also provide for hot or cold implantation of ions.

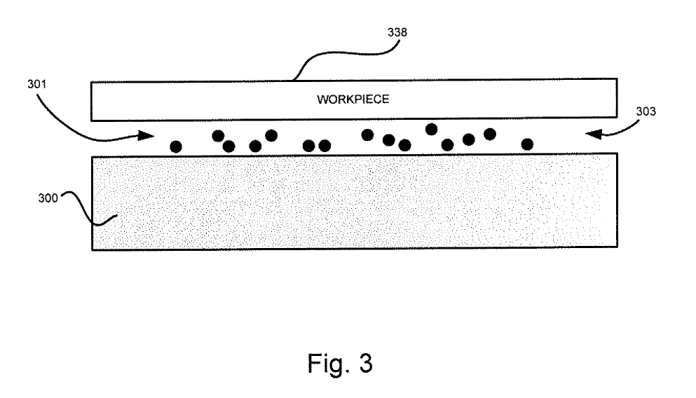

As discussed above, to improve amorphization, a workpiece may be cooled. FIG. 3 depicts a chuck 300 for performing backside gas thermal coupling according to an embodiment of the present disclosure. The chuck 300 may have a backside gas apparatus to perform backside gas thermal coupling. In one embodiment, the backside gas thermal coupling may be performed in a plasma doping system as shown in FIG. 1. In another embodiment, the backside gas thermal coupling may be performed in a beam-line ion implanter as shown in FIG. 2. Other various implementations and applications may also be provided.

Referring to FIG. 3, as gas atoms or molecules 301 flow between a workpiece 338 and the chuck 300, the gas atoms or molecules 301 may strike the surface of the chuck 300 and acquire translational and rotational energies corresponding to the temperature of the chuck 300. The energy corresponding to the temperature of the chuck 300 may be described using an accommodation coefficient that describes coupling experienced between the atoms or molecules 301 and the surface of the chuck 300 where they strike. In this example, an accommodation coefficient may depend on details of the atoms or molecules 301 (e.g., degrees of freedom) and details of a striking surface (e.g., roughness or sticking coefficient).

The thermalized atoms or molecules 301 may then travel across a gap 303 between the workpiece 338 and the chuck 300. If the distance between the workpiece 338 and the chuck 300 is small compared to a mean free path of the atoms or molecules 301 (e.g., the average distance traveled between collisions), the trip across the gap 303 may be a direct path. When atoms or molecules 301 reach the workpiece 338, the same thermalization process may occur with workpiece 338. For example, in one embodiment, if the workpiece 338 is hotter than the chuck 300, the atoms or molecules 301 may absorb energy from the workpiece 138. On the other hand, if the chuck 300 is hotter than the workpiece 338, then the atoms or molecules 301 may absorb energy from the chuck 300. Therefore, as the atoms or molecules 301 travel between the workpiece 338 and the chuck 300, the two surfaces may be brought toward the same temperature. In this manner, the workpiece 338 may be either heated or cooled. This heat transfer may be made less efficient if there are large numbers of collisions between the atoms or molecules 301 because the atoms or molecules will then share energy between each other.

Although a higher gas pressure implies more atoms or molecules 301 to transfer heat between the workpiece 338 and the chuck 300, it may also imply a shorter mean free path. Thus, at low pressure, heat transfer may be proportional to gas pressure. As pressure rises to a point where the mean free path drops to the gap 303 between the chuck 300 and the workpiece 338, the increase may start to fall off. Higher pressure may be used by keeping the workpiece 338 nearer to the chuck 300. It should be appreciated that in most cases, clamping pressure is generally higher than backside gas pressure. Other variations may also be provided.

In another embodiment, a thermal conditioning unit may be used to cool a workpiece. For example, the workpiece may rest upon a thermal conditioning unit. In one embodiment, for instance, a robotic arm may move the workpiece between the thermal conditioning unit and the chuck, and the workpiece may be cooled to below room temperature.

It should be appreciated that a workpiece may be cooled to various predetermined temperatures to optimize amorphization. For example, the cooling range may be below room temperature to −212° C. In one embodiment, the workpiece may be cooled to 0° C. or below freezing. In another embodiment, the workpiece may be chilled to between −20° C. and −100° C. In yet another embodiment, the workpiece may be chilled to approximately −60° C. Other various chilling temperatures may be utilized.

Accordingly to another embodiment, a pre-chiller may be used in an end station or process chamber to cool a workpiece. For example, in one embodiment, the pre-chiller may be a platform within an end station or process chamber. In another embodiment, pre-chilling may take place in a load lock. In yet another embodiment, a platen may chill a workpiece in a manner similar to that described in FIG. 3. Other various embodiments may also be implemented. For instance, these may include other cooling processes disclosed in U.S. patent application Ser. No. 11/504,367 England et al. filed Aug. 15, 2006, U.S. patent application Ser. No. 11/525,878 Blake et al. filed Sep. 23, 2006, and U.S. patent application Ser. No. 11/733,445 England et al. filed Apr. 10, 2007, which are all hereby incorporated by reference.

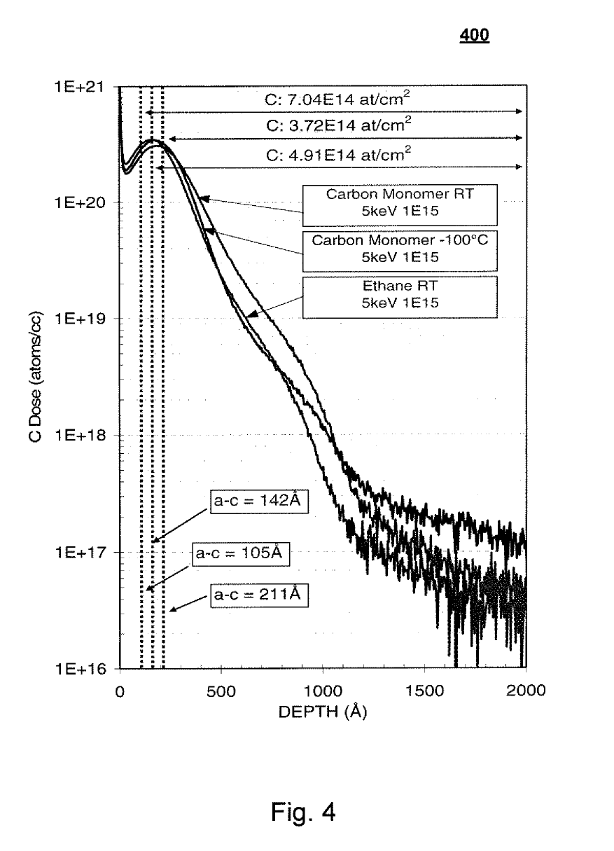

FIG. 4 depicts an exemplary graph 400 illustrating the effect of ethane, a carbon molecule, compared to simple carbon monomers, according to an embodiment of the present disclosure. In this example, the use of ethane as a carbon-containing species is shown to increase the amorphization by approximately 50% and may create a substantially abrupt profile ideal for ion implantation.

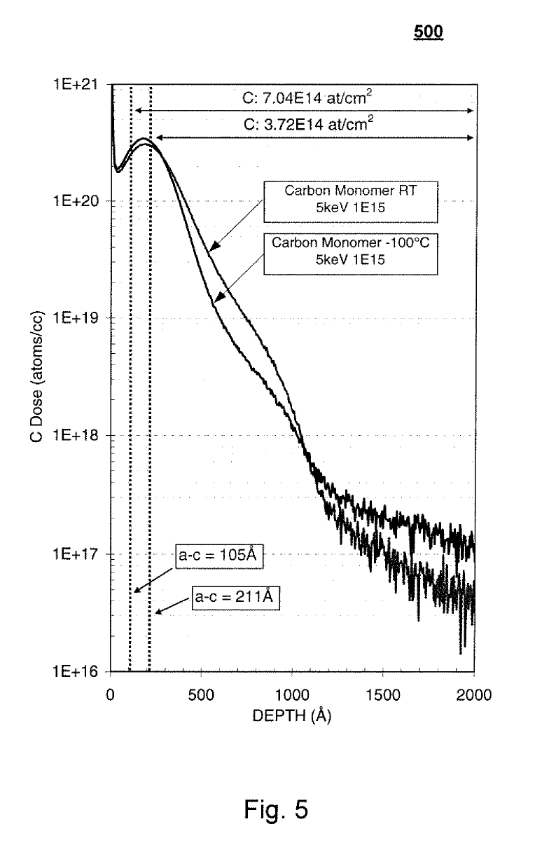

FIG. 5 depicts an exemplary graph 500 illustrating the effect of temperature on carbon implantation according to an alternative embodiment of the present disclosure. Implanting carbon at a lower temperature, such as −100° C. as depicted, may increase amorphization by approximately 100%. Furthermore, a carbon dose beyond the amorphization layer may be reduced.

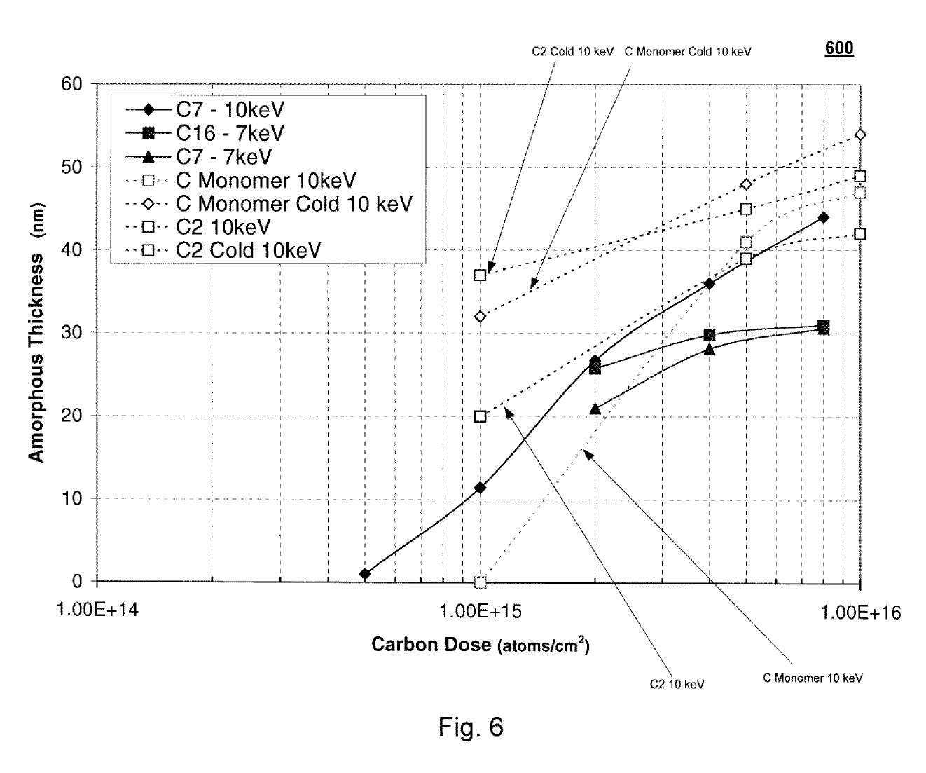

FIG. 6 depicts an exemplary graph 600 illustrating and comparing carbon dose and amorphous thickness for various carbon implants according to another embodiment of the present disclosure. In this embodiment, the amorphous thickness is shown to increase when cold implantation is performed as compared to standard implantation.

Accordingly, a cold implant of a carbon-containing species may improve both ultra-shallow implants and strain engineering. For example, a carbon-containing species may be implanted under cold conditions, such as at −60° C. Furthermore, a cold implant of a carbon-containing species may be performed alone or with another species, such as germanium, as a PAI.

In addition, a cold implant of a carbon-containing species may be performed to fabricate an ultra-shallow junction (USJ). To implant a USJ, a workpiece may be amorphized so that dopants (e.g., boron, phosphorus, etc.) do not channel within the crystal lattice of the workpiece. Carbon may be implanted to create an amorphous layer. For instance, cold implantation of carbon may provide better activation of boron or phosphorus. The cold temperature makes the dopant profile shallower and also prevents channeling within the crystal lattice of the workpiece. Specifically, carbon may compete with boron or phosphorus for activation sites and may therefore inhibit diffusion of boron or phosphorus. It should be appreciated that while only one example is described, other ultra-shallow implants may be performed in a similar manner by cold implantation of a carbon-containing species.

Furthermore, a cold implant of a carbon-containing species may be performed to create strain. Carbon that is implanted into a workpiece to create strain may knock atoms out of the crystal lattice of the workpiece. For example, these may be silicon or germanium atoms. If the carbon-containing species is a molecular compound with multiple carbon atoms, then there may be an increased chance that the carbon atoms may knock out an atom from the crystal lattice of the workpiece. Thus, the implantation of a carbon-containing species may increase amorphization and strain.

Accordingly, implantation of carbon molecules under cold temperature conditions may substantially improve the effects of amorphization and strain and optimize ion implantation, particularly in fabricating a USJ.

It should also be appreciated that while embodiments of the present disclosure are directed towards implantation using a plasma doping system operating in an RF mode, other implementations, systems, and/or modes of operation may also be provided. For example, these may include other plasma-based ion implantation systems, such as glow discharge plasma doping (GD-PLAD) or other ion implantation system.

It should also be appreciated that while embodiments of the present disclosure are described using carbon-containing species, other implantation species may also be provided. For example, these may include fluorine containing molecules (e.g., boron difluoride (BF₂)) or arsenic or phosphorus containing molecules, such as arsenic or phosphorus dimers (e.g., As₂ or P₂) or tetremers (As₄ or P₄).

It should also be appreciated that the disclosed embodiments not only provide several modes of operation, but that these various modes may provide additional implantation customizations that would not otherwise be readily provided.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method for ion implantation, the method comprising:
cooling a target material to a predetermined temperature; and
implanting the target material with a carbon-containing species at the predetermined temperature to improve at least one of strain and amorphization.

2. The method of claim 1, wherein the target material is cooled by at least one of a backside cooling, thermal conditioning cooling, and pre-chilling.

3. The method of claim 1, wherein the predetermined temperature is below room temperature and above −212° C.

4. The method of claim 1, wherein the predetermined temperature is in the range of −20° C. to −100° C.

5. The method of claim 1, wherein the carbon-containing species is molecular carbon comprising at least one of carbon, diborane, pentaborane, carborane, octaborane, decaborane, and octadecaborane.

6. The method of claim 1, wherein the carbon-containing species is an alkane or alkene comprising at least one of methane, ethane, propane, bibenzyl, butane, and pyrene.

7. The method of claim 1, further comprising implanting the target material with an additional species for improved pre-amorphization implantation (PAI) or improved conductance of the target material.

8. The method of claim 8, wherein the additional species comprises at least one of germanium (Ge), boron (B), phosphorus (P), silicon (Si), arsenic (As), xenon (Xe), carbon (C), nitrogen (N), aluminum (Al), magnesium (Mg), silver (Ag), gold (A), carborane (C₂B₁₀H₁₂), boron difluoride (BF2), decaborane, octadecaborane, and diborane.

9. The method of claim 1, wherein the method is used to at least create strain and fabricate an ultra-shallow junction (USJ) in the target material.

10. The method of claim 1, further comprising controlling at least one of dose, dose rate, number of atoms in the carbon-containing species, atomic energy, and pressure to further improve at least one of strain and amorphization.

11. An apparatus for ion implantation, the apparatus comprising:
a cooling device for cooling a target material to a predetermined temperature; and
an ion implanter for implanting the target material with a carbon-containing species at the predetermined temperature to improve at least one of strain and amorphization.

12. The apparatus of claim 11, wherein the cooling device comprises at least one of a backside cooling device, a thermal conditioning unit, and a pre-chiller.

13. The apparatus of claim 11, wherein the predetermined temperature is below room temperature and above −212° C.

14. The apparatus of claim 11, wherein the predetermined temperature is in the range of −20° C. to −100° C.

15. The apparatus of claim 11, wherein the carbon-containing species is molecular carbon comprising at least one of carbon, diborane, pentaborane, carborane, octaborane, decaborane, and octadecaborane.

16. The apparatus of claim 11, wherein the carbon-containing species is an alkane or alkene comprising at least one of methane, ethane, propane, bibenzyl, butane, and pyrene.

17. The apparatus of claim 11, wherein the ion implanter is a plasma doping system or a beam-line ion implanter.

18. The apparatus of claim 11, wherein the ion implanter further implants the target material with an additional species for improved pre-amorphization implantation (PAI) or improved conductance of the target material.

19. The apparatus of claim 18, wherein the additional species comprises at least one of germanium (Ge), boron (B), phosphorus (P), silicon (Si), arsenic (As), xenon (Xe), carbon (C), nitrogen (N), aluminum (Al), magnesium (Mg), silver (Ag), gold (A), carborane (C₂B₁₀H₁₂), boron difluoride (BF2), decaborane, octadecaborane, and diborane.

20. The apparatus of claim 11, further comprising one or more controllers for controlling at least one of dose, dose rate, number of atoms in the carbon-containing species, atomic energy, and pressure to improve at least one of strain and amorphization.

21. An apparatus for ion implantation, the apparatus comprising:
a means for cooling a target material to a predetermined temperature; and
a means for implanting the target material with a carbon-containing species at the predetermined temperature to improve at least one of strain and amorphization.
